(19) United States
(12) Patent Application Publication
(10) Pub. No.: US 2026/0136919 A1
(43) Pub. Date: May 14, 2026

(54) SEMICONDUCTOR DEVICE AND MANUFACTURING METHOD THEREFOR

(71) Applicant: CXMT Corporation, Hefei City (CN)

(72) Inventors: HUALIANG YU, Hefei City, Anhui Province (CN); Hui ZONG, Hefei City, Anhui Province (CN); Yanzhao XING, Hefei City, Anhui Province (CN); Wei FENG, Hefei City, Anhui Province (CN); Xiaoxian WU, Hefei City, Anhui Province (CN); Zhihao HAN, Hefei City, Anhui Province (CN)

(73) Assignee: CXMT Corporation, Hefei City (CN)

(21) Appl. No.: 19/428,114

(22) Filed: Dec. 20, 2025

Related U.S. Application Data
(63) Continuation of application No. PCT/CN2025/131567, filed on Oct. 31, 2025.

(30) Foreign Application Priority Data
Nov. 11, 2024 (CN) 202411605386.9

(51) Int. Cl. H10W 20/41; H10B 12/00; H10D 1/68

(52) U.S. Cl. CPC H10W 20/435; H10B 12/03; H10B 12/31; H10D 1/716

(57) ABSTRACT

The present disclosure a semiconductor device, includes: a plurality of active regions disposed in a first region, each active region including a first connection terminal and a second connection terminal; a plurality of first capacitors disposed in the first region, where each first capacitor includes a first upper electrode and a first lower electrode; a plurality of second capacitors disposed in a second region, each second capacitor including a second upper electrode and a second lower electrode; a plurality of first bonding pads disposed in the first region, at least one first bonding pad being connected to the second connection terminal of at least one active region; and a plurality of second bonding pads disposed in the second region, at least one second bonding pad being connected to the second lower electrode of at least one second capacitor.

### CROSS-REFERENCE TO RELATED APPLICATIONS

This application is a continuation of International Patent Application No. PCT/CN2025/131567 filed on Oct. 31, 2025, which claims priority to Chinese Patent Application No. 202411605386.9 filed on Nov. 11, 2024. The disclosures of the above-referenced applications are hereby incorporated by reference in their entirety.

### TECHNICAL FIELD

Embodiments of the present disclosure relate to the technical field of semiconductors, and in particular, to a semiconductor device and a manufacturing method therefor.

### BACKGROUND

Transistors and capacitors are important components of DRAM devices. In a DRAM device, a transistor mainly functions as a switch for controlling the charging and discharging of a capacitor, i.e., the writing and reading of data. A transistor typically includes three key components: a source, a drain, and a gate. Dopants (such as arsenic or boron) are generally introduced into the source and the drain by using an ion implantation technology to form an n-type or p-type semiconductor region. The implanted dopant atoms may be initially in an inactive state; that is, the dopant atoms do not effectively participate in the conductivity process of the semiconductor, and the doping activation of the source and drain regions needs to be achieved through a heat treatment process. This process is usually referred to as activation annealing, and the annealing temperature is usually greater than 500° C.

The H-K material acts as the dielectric layer of the capacitor, which can significantly reduce the physical dimensions of the capacitor while maintaining or increasing the capacitance value of the capacitor. Generally speaking, the H-K material will crystallize at about 500° C., resulting in increased leakage. In addition, since the DRAM device includes a plurality of different regions, the pattern composition of different regions will be different. These differences in pattern composition will also cause local thermal stress due to high temperature, resulting in product defects and affecting the production yield.

### SUMMARY

Embodiments of the present disclosure provide a semiconductor device with a higher integration level and a manufacturing method therefor.

The problems to be solved by the technical spirit of the present disclosure are not limited to the above-mentioned problems, and those skilled in the art will clearly understand other unmentioned problems from the following description.

Some embodiments of the present disclosure provide a semiconductor device. The semiconductor device includes: a first region and a second region; a plurality of active regions, where the plurality of active regions are disposed in the first region, and each of the plurality of active regions includes a first connection terminal and a second connection terminal; a plurality of first capacitors, where the plurality of first capacitors are disposed in the first region, each of the plurality of first capacitors includes a first upper electrode and a first lower electrode, and the first lower electrode of each first capacitor is connected to the first connection terminal; a plurality of second capacitors, where the plurality of second capacitors are disposed in the second region, and each of the plurality of second capacitors includes a second upper electrode and a second lower electrode; a plurality of first bonding pads, where the plurality of first bonding pads are disposed in the first region, and at least one of the plurality of first bonding pads is connected to the second connection terminal of at least one of the plurality of active regions; and a plurality of second bonding pads, where the plurality of second bonding pads are disposed in the second region, and at least one of the plurality of second bonding pads is connected to the second lower electrode of at least one of the plurality of second capacitors.

Some embodiments of the present disclosure further provide a method for manufacturing a semiconductor device. The method includes: providing a substrate, where the substrate is provided with a first region and a second region; patterning a part of the substrate to form a plurality of active regions in the first region, where each of the plurality of active regions includes a first connection terminal and a second connection terminal; forming a plurality of first capacitors and a plurality of second capacitors in the first region and the second region separately, where each of the plurality of first capacitors includes a first upper electrode and a first lower electrode, the first lower electrode of each first capacitor being connected to the first connection terminal, and each of the plurality of second capacitors includes a second upper electrode and a second lower electrode; removing a part of the substrate that is not patterned; and forming a plurality of first bonding pads in the first region and forming a plurality of second bonding pads in the second region, where at least one of the plurality of first bonding pads is connected to the second connection terminal of at least one of the plurality of active regions, and at least one of the plurality of second bonding pads is connected to the second lower electrode of at least one of the plurality of second capacitors.

### BRIEF DESCRIPTION OF DRAWINGS

The drawings, which are incorporated in and constitute a part of this specification, illustrate embodiments consistent with the embodiments of the present disclosure and, together with the specification, serve to explain the principles of the embodiments of the present disclosure.

FIG. 1 is a schematic plan view of a semiconductor device according to the embodiments of the present disclosure.

FIGS. 2 and 3 are cross-sectional views of a semiconductor device according to the embodiments of the present disclosure.

FIG. 4A is a schematic plan view of a semiconductor device according to the embodiments of the present disclosure.

FIGS. 4B and 4C are cross-sectional views taken along lines BB and CC in FIG. 4A, respectively.

FIGS. 5 and 6 are cross-sectional views of a semiconductor device according to the embodiments of the present disclosure.

FIG. 7 is a schematic flow chart of a method for manufacturing a semiconductor device according to the embodiments of the present disclosure.

FIGS. 8 to 11B are schematic cross-sectional views of a semiconductor device corresponding to respective steps in a method for manufacturing a semiconductor structure according to the embodiments of the present disclosure.

Through the above drawings, explicit embodiments of the embodiments of the present disclosure have been illustrated, and more detailed descriptions will follow. These drawings and textual descriptions are not intended to limit the scope of the inventive concept of the embodiments of the present disclosure in any way, but rather to explain the concepts of the embodiments of the present disclosure to those skilled in the art by referring to specific embodiments.

### DESCRIPTION OF EMBODIMENTS

The technical solutions in embodiments of the present disclosure will be clearly and completely described hereinafter with reference to the drawings in the embodiments of the present disclosure. It can be understood that the specific embodiments described herein are merely illustrative of the related disclosures and are not intended to limit the present disclosure. In addition, it should be further noted that for the convenience of description, only the relevant portions are shown in the drawings. Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure. In the following description, reference is made to “some embodiments”, which describe subsets of all possible embodiments, but it can be understood that “some embodiments” may be the same subset or different subsets of all possible embodiments, and may be combined with each other without conflict. It should be noted that the terms “first\second\third” referred to in the embodiments of the present disclosure are merely used for distinguishing similar objects and do not represent a specific ordering for the objects. It can be understood that “first\second\third” may be subjected to interchange of a specific order or sequence if permitted, such that the embodiments of the present disclosure described herein can be implemented in an order other than that shown or described.

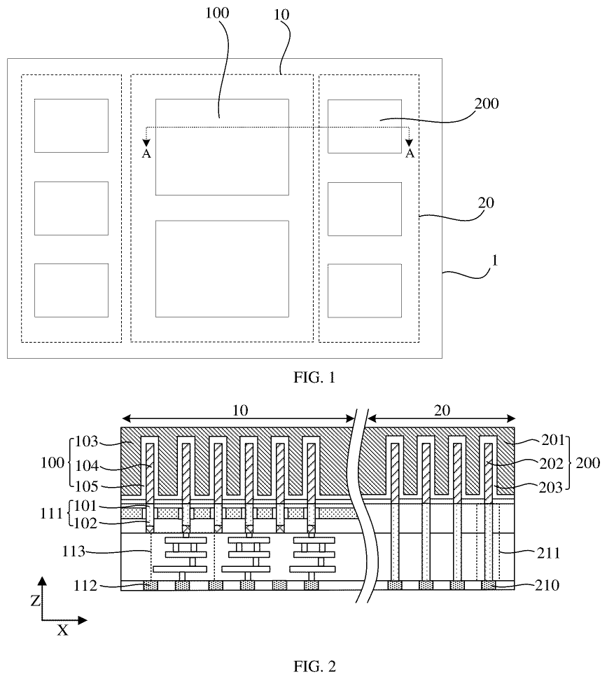

FIG. 1 illustrates a top view of a semiconductor device according to some embodiments of the present disclosure. The semiconductor device includes a base plate 1. The base plate 1 is provided with a first region 10 and a second region 20. A memory cell, such as a memory cell composed of a transistor and a capacitor, is formed in the first region 10, and a non-memory cell, such as a non-memory cell including only a capacitor or featuring other functions, is formed in the second region 20. The second region 20 may be disposed around the first region 10, or may be disposed on one or more sides of the first region 10. The position relationship between the first region 10 and the second region 20 is not limited by a position shown in FIG. 1.

The base plate 1 may be or may include a wafer including silicon, germanium, silicon-germanium, or a group III-V compound such as GaP, GaAs, or GaSb. In some exemplary embodiments, the base plate 1 may be a silicon-on-insulator (SOI) wafer or a germanium-on-insulator (GOI) wafer, and may be doped or undoped. In some exemplary embodiments, the base plate 1 may include both silicon, germanium, silicon-germanium, or a group III-V compound-based crystal such as GaP, GaAs, or GaSb, and a non-semiconductor material, such as an insulating dielectric layer and a metal wiring layer. In some embodiments, the base plate 1 may also be only a part carrying the semiconductor device, and the material thereof is not particularly limited.

With continued reference to FIG. 2, FIG. 2 is a cross-sectional view of a semiconductor device according to some embodiments of the present disclosure. Specifically, FIG. 2 is a cross-sectional view taken along line AA in FIG. 1. The first region 10 is provided with a plurality of active regions 111, the active regions 111 extend in a third direction Z, and the active regions 111 are spaced apart in a first direction X, where the third direction Z may be a direction perpendicular to the base plate 1, and the first direction X may be a direction parallel to the base plate 1. An included angle exists between the first direction X and the third direction Z. For example, the included angle between the first direction X and the third direction Z is 90°. Each active region 111 includes a first connection terminal 101 and a second connection terminal 102. The first connection terminal 101 and the second connection terminal 102 may be parts of the end parts of each active region 111. The active region 111 may be an actual operating region of an active device such as a transistor or a diode, that is, a region in the device that participates in charge carrier (electron and hole) transport and control. The active region 111 typically includes a source, a drain, and a channel region. These regions are doped to form specific electrical characteristics, so that the transistor is capable of controlling current flow. In some embodiments of the present disclosure, the first connection terminal 101 of each active region 111 may be a source, and the second connection terminal 102 of each active region 111 may be a drain.

With continued reference to FIG. 2, a plurality of first capacitors 100 are disposed in the first region 10 of the semiconductor device, and each first capacitor 100 includes a first upper electrode 103, a first lower electrode 104, and a first dielectric layer 105 disposed between the first upper electrode 103 and the first lower electrode 104. In some embodiments, each first capacitor 100 may be a capacitor of a DRAM memory cell. In this case, the first upper electrodes 103 of the first capacitors 100 are connected to each other, the first dielectric layers 105 of the first capacitors 100 are connected to each other, the first lower electrodes 104 of the first capacitors 100 are isolated from each other, and the first lower electrodes 104 of the first capacitors 100 are correspondingly connected to the first connection terminals 101 of the active regions 111. The first dielectric layer 105 is disposed around the outer peripheral surface of the first lower electrode 104, and the first upper electrode 103 is disposed around the outer peripheral surface of the first dielectric layer 105. The first capacitor 100 shown in FIG. 2 is a pillar capacitor (pillar capacitor), and the first capacitor 100 may alternatively be a capacitor of another type.

In some embodiments, the first upper electrode 103 is disposed above the first dielectric layer 105 and is made of a conductive material, which may be polycrystalline silicon, metal, or a composite layer composed of polycrystalline silicon and metal. The metal may be, for example, tungsten or other metal materials suitable for the upper electrode of the DRAM. The first lower electrode 104 is typically made of a conductive material, such as doped polycrystalline silicon or a metal material. The first dielectric layer 105 may be an H-K (high dielectric constant) material, such as hafnium oxide (HfO₂) or hafnium silicate (HfSiOₓ), to increase the capacitance value.

With continued reference to FIG. 2, a plurality of second capacitors 200 are disposed in the second region 20 of the semiconductor device, and each second capacitor 200 includes a second upper electrode 201, a second lower electrode 202, and a second dielectric layer 203 disposed between the second upper electrode 201 and the second lower electrode 202. In some embodiments, each second capacitor 200 may be a capacitor of the same type as each first capacitor 100. In this case, the second upper electrodes 201 of the second capacitors 200 are connected to each other, the second dielectric layers 203 of the second capacitors 200 are connected to each other, the second lower electrodes 202 of the second capacitors 200 are isolated from each other, the second dielectric layer 203 is disposed around the outer peripheral surface of the second lower electrode 202, and the second upper electrode 201 is disposed around the outer periphery of the second dielectric layer 203. In some embodiments, each second upper electrode 201 has the same composition as each first upper electrode 103, each second lower electrode 202 has the same composition as each first lower electrode 104, and the second dielectric layer 203 has the same composition as the first dielectric layer 105.

With continued reference to FIG. 2, a plurality of first bonding pads 112 are further disposed in the first region 10 of the semiconductor device, and a plurality of second bonding pads 210 are further disposed in the second region 20 of the semiconductor device. The first bonding pads 112 and the second bonding pads 210 may be conductive pads formed of metal or other conductive materials, and the first bonding pads 112 and the second bonding pads 210 may be disposed on the surface of the semiconductor device for connection to other semiconductor devices. For example, the first bonding pads 112 and the second bonding pads 210 are both conductive pads for direct bonding, such as copper pads. A material layer for direct bonding is further disposed between the first bonding pad 112 and the second bonding pad 210, which may not only provide mutual isolation between the first bonding pad 112 and the second bonding pad 210, but also increase the bonding strength of the first bonding pad 112 and the second bonding pad 210 to jointly form the interface of hybrid bonding (hybrid bonding).

In some embodiments, at least one first bonding pad 112 is electrically connected to at least one second connection terminal 102, and at least one second bonding pad 210 is electrically connected to at least one second lower electrode 202. In some embodiments, a part of the first bonding pads 112 and a part of the second bonding pads 210 may be dummy connection pads that are not electrically connected to any structure in the semiconductor device. In some embodiments, all the first bonding pads 112 and all the second bonding pads 210 may be active connection pads that are electrically connected to structures in the semiconductor device.

With continued reference to FIG. 2, in some embodiments, a first interconnection structure 113 and a second interconnection structure 211 are further disposed in the first region 10 and the second region 20 of the semiconductor device, respectively. The first interconnection structure 113 is disposed between the second connection terminal 102 of the active region 111 and the first bonding pad 112 for connecting the second connection terminal 102 and the first bonding pad 112, thereby achieving communication between the second connection terminal 102 of the active region 111 and the first bonding pad 112. The second interconnection structure 211 is disposed between the second lower electrode 202 of the second capacitor 200 and the second bonding pad 210 for connecting the second lower electrode 202 of the second capacitor 200 and the second bonding pad 210.

In some embodiments, the first interconnection structure 113 may be an interconnection structure composed of a plurality of layers of metal wirings, for example, an interconnection structure composed of two or more layers of metal tungsten. The second interconnection structure 211 may be an interconnection structure composed of one or more layers of metal wirings, for example, an interconnection structure formed of one layer of metal tungsten.

In some embodiments, the first capacitor 100 and the second capacitor 200 are capacitors for achieving different functions. The first capacitor 100 is configured to store charges, and is connected to a corresponding read/write circuit via the first bonding pad 112, so as to use the first capacitor 100 to read or write data. The second capacitor 200 may be a capacitor for stabilizing a power supply voltage and reducing signal noise, for example, a decoupling capacitor, which is connected to a corresponding functional circuit via the second bonding pad 210 and may reduce the noise of an internal power supply voltage provided to an address decoder, for example, high-frequency noise.

In some embodiments, a part of the first bonding pads 112 may be further connected to the first upper electrode 103 of each first capacitor 100, and a part of the second bonding pads 210 may be further connected to the second upper electrode 201 of each second capacitor 200, so as to respectively connect the first upper electrode 103 and the second upper electrode 201 to a specific signal circuit.

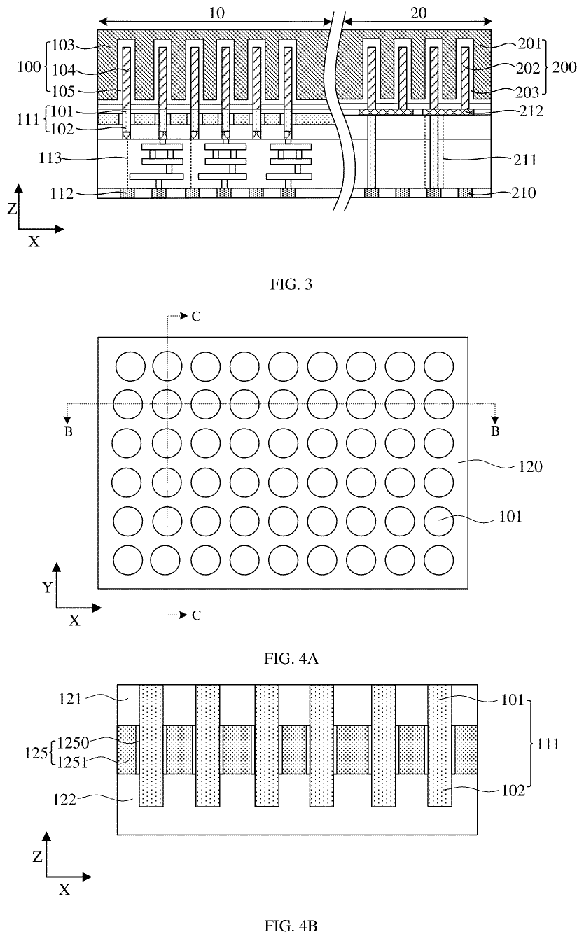

In some embodiments, as shown in FIG. 3, FIG. 3 is a cross-sectional view of a semiconductor device according to some embodiments of the present disclosure. A common connection terminal 212 is further disposed in the second region 20 of the semiconductor device. The common connection terminal 212 is disposed below the second capacitors 200 for simultaneous connection to a plurality of second lower electrodes 202, so as to serve as a common lower electrode terminal for the plurality of second capacitors 200. In this case, the second interconnection structure 211 is disposed between the common connection terminal 212 and the second bonding pad 210 for connecting the common connection terminal 212 and each second bonding pad 210. In these embodiments, since the plurality of second lower electrodes 203 are connected through the common connection terminal 212, the number of second interconnection structures 211 may be reduced, and a part of the second bonding pads 210 may be dummy connection terminals that are not connected to the common connection terminal 212. In these embodiments, the lower electrodes of the plurality of second capacitors 200 are connected through the common connection terminal 212, thereby obtaining greater capacitance.

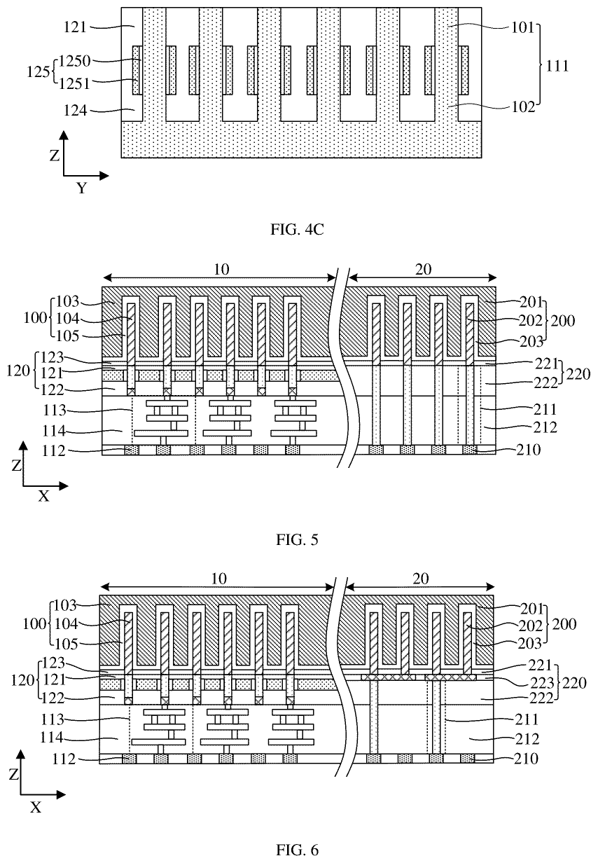

In some embodiments, the first connection terminals 101 of the active regions 111 in the first region 10 are spaced apart from each other. As shown in FIGS. 4A to 4C, FIG. 4A is a schematic plan view of distribution of the active regions 111, FIG. 4B is a cross-sectional view taken along line BB in FIG. 4A, and FIG. 4C is a cross-sectional view taken along line CC in FIG. 4A. As shown in FIGS. 4A to 4C, the first connection terminals 101 of the active regions 111 are spaced apart from each other in the first direction X and the second direction Y, and the first connection terminals 101 may be in the shape of a cylinder or in other shapes. The second connection terminals 102 of the active regions 111 are isolated from each other in the first direction X, and the second connection terminals 102 of the active regions 111 are connected to each other in the second direction Y. In some embodiments, the semiconductor device further includes gate structures 125 disposed in the active regions 111. The gate structure 125 surrounds the active region between the first connection terminal 101 and the second connection terminal 102 for controlling the on-off of the first connection terminal 101 and the second connection terminal 102. In the first direction X, the gate structures 125 are connected to each other, and in the second direction Y, the gate structures 125 are isolated from each other. The gate structure 125 may include a gate dielectric layer 1250 and a gate conductive layer 1251. The gate dielectric layer 1250 may be disposed between the gate conductive layer 1251 and the active region 111. The second direction Y may be a direction parallel to the base plate 1, and there is an included angle between the second direction Y and the first direction X, for example, an included angle of 90°.

With continued reference to FIGS. 4A to 4C and 5, FIG. 5 is a cross-sectional view of the semiconductor device. The semiconductor device further includes a first dielectric layer combination 120 disposed in the first region 10 and a second dielectric layer combination 220 located in the second region 20. The first dielectric layer combination 120 includes a first isolation dielectric layer 122, and the first isolation dielectric layer 122 is disposed between the second connection terminals 102 arranged in the first direction X for isolating the second connection terminals 102. A second isolation dielectric layer 222 is disposed between the second interconnection structures 211 for isolating the second interconnection structures 211. The first isolation dielectric layer 122 and the second isolation dielectric layer 222 may be of a single-layer structure or a multi-layer composite structure, and the materials of the first isolation dielectric layer 122 and the second isolation dielectric layer 222 are the same or different. For example, in some embodiments, the first isolation dielectric layer 122 and the second isolation dielectric layer 222 are both made of silicon nitride, silicon oxide, or L-K (low dielectric constant) dielectric materials; in some embodiments, the first isolation dielectric layer 122 is made of silicon oxide or silicon nitride, and the second isolation dielectric layer 222 is made of silicon nitride or silicon oxide.

With continued reference to FIG. 5, the first dielectric layer combination 120 further includes a first insulating dielectric layer 121, and the first insulating dielectric layer 121 is disposed between the first connection terminals 101 for isolating the first connection terminals 101. The second dielectric layer combination 220 further includes a second insulating dielectric layer 221, and the second insulating dielectric layer 221 is disposed between the second lower electrodes 202 for isolating the second lower electrodes 202. The first insulating dielectric layer 121 and the second insulating dielectric layer 221 may be of a single-layer structure or a multi-layer composite structure, and the materials of the first insulating dielectric layer 121 and the second insulating dielectric layer 221 are the same or different. For example, in some embodiments, the first insulating dielectric layer 121 and the second insulating dielectric layer 221 are both made of silicon nitride, silicon oxide, or L-K dielectric materials; in some embodiments, the first insulating dielectric layer 121 is made of silicon oxide, and the second insulating dielectric layer 221 is made of silicon nitride.

In some embodiments, the materials of the first isolation dielectric layer 122 and the first insulating dielectric layer 121 may be the same or different. In some embodiments, the first isolation dielectric layer 122 and the first insulating dielectric layer 121 are made of silicon oxide and silicon nitride, respectively. In some embodiments, the first isolation dielectric layer 122 and the first insulating dielectric layer 121 are both made of silicon nitride or silicon oxide. The materials of the second isolation dielectric layer 222 and the second insulating dielectric layer 221 may be the same or different. In some embodiments, the second isolation dielectric layer 222 and the second insulating dielectric layer 221 are made of silicon oxide and silicon nitride, respectively. In some embodiments, the second isolation dielectric layer 222 and the second insulating dielectric layer 221 are both made of silicon nitride or silicon oxide.

With continued reference to FIGS. 3 and 6, FIG. 6 is a cross-sectional view of the semiconductor device. When the second lower electrodes 202 of the second capacitors 200 are connected to each other through the common connection terminal 212, the first dielectric layer combination 120 and the second dielectric layer combination 220 are correspondingly disposed in the first region 10 and the second region 20, respectively. The first dielectric layer combination 120 includes a first isolation dielectric layer 122 and a first insulating dielectric layer 121, and the second dielectric layer combination 220 includes a second isolation dielectric layer 222 and a second insulating dielectric layer 221. The first isolation dielectric layer 122 is disposed between the second connection terminals 102 arranged in the first direction X, and is configured to isolate the second connection terminals 102 in the first direction X; the first insulating dielectric layer 121 is disposed between the first connection terminals 101 for isolating the first connection terminals 101. The second isolation dielectric layer 222 is disposed between second interconnection structures 211 for isolating the second interconnection structures 211, and the second insulating dielectric layer 221 is disposed between the second lower electrodes 202 for isolating the second lower electrodes 202. In these embodiments, the materials of the first isolation dielectric layer 122, the first insulating dielectric layer 121, the second isolation dielectric layer 222, and the second insulating dielectric layer 221 may be the same or different. For example, the first isolation dielectric layer 122 and the second isolation dielectric layer 222 may both be made of silicon oxide, and the first insulating dielectric layer 121 and the second insulating dielectric layer 221 may both be made of silicon nitride.

With continued reference to FIG. 5, in some embodiments, the first dielectric layer combination 120 further includes a first isolation layer 123, and the first isolation layer 123 may be disposed on the first insulating dielectric layer 121 and between the first lower electrodes 104 for isolating the first lower electrodes 104. In some embodiments, the first isolation layer 123 and the first insulating dielectric layer 121 may be made of the same or different materials. For example, the first isolation layer 123 and the first insulating dielectric layer 121 are each made of one of silicon oxide or silicon nitride. When the first isolation layer 123 and the first insulating dielectric layer 121 are made of the same material, there may be no obvious boundary between the first isolation layer 123 and the first insulating dielectric layer 121.

With continued reference to FIGS. 3 and 6, in some embodiments, the second dielectric layer combination 220 further includes a second isolation layer 223. The second isolation layer 223 is disposed between the second isolation dielectric layer 222 and the second insulating dielectric layer 221, and the second isolation layer 223 is disposed between adjacent common connection terminals 212 for isolating the common connection terminals 212. In some embodiments, the second isolation layer 223 and the second insulating dielectric layer 221 may be made of the same or different materials. For example, the second isolation layer 223 and the second insulating dielectric layer 221 are each made of one of silicon oxide or silicon nitride. When the second isolation layer 223 and the second insulating dielectric layer 221 are made of the same material, there may be no obvious boundary between the second isolation layer 223 and the second insulating dielectric layer 221. In some embodiments, the second isolation layer 223 and the second insulating dielectric layer 221 are both made of silicon nitride, and the second isolation dielectric layer 222 is made of silicon oxide.

With continued reference to FIGS. 5 and 6, in some embodiments, the first region 10 of the semiconductor device further includes an insulating dielectric layer 114 and an insulating dielectric layer 224 located in the second region 20. The insulating dielectric layer 114 is disposed between first interconnection structures 113 to isolate the first interconnection structures 113; the insulating dielectric layer 224 is disposed between second interconnection structures 211 to isolate the second interconnection structures 211. In some embodiments, the insulating dielectric layer 114 and the insulating dielectric layer 224 may be of a single-layer structure or a multi-layer composite structure, for example, a combination of one or more of silicon nitride, silicon oxide, or an L-K dielectric material.

With continued reference to FIG. 4C, the semiconductor device further includes an isolation dielectric layer 124 disposed between the second connection terminals 102 in the second direction Y. The isolation dielectric layer 124 may be a single-layer or multi-layer composite structure, and the material of the isolation dielectric layer 124 may be the same as, partially the same as, or different from the materials of the first isolation dielectric layer 122 and the first insulating dielectric layer 121. For example, the isolation dielectric layer 124 may be a composite structure composed of silicon oxide and silicon nitride, the first isolation dielectric layer 122 is made of silicon oxide, and the first insulating dielectric layer 121 is made of silicon nitride. In some other embodiments, the isolation dielectric layer 124, the first isolation dielectric layer 122, and the first insulating dielectric layer 121 may also be other types of dielectric materials, which will not be repeated here.

The semiconductor device according to the embodiments of the present disclosure is provided with capacitors on both the first region and the second region, and the capacitors corresponding to the respective regions are connected to the bonding pads in different ways, so that the capacitors of the respective regions are allocated to different functional regions to achieve different functions, thereby further broadening the application value of the semiconductor device. Meanwhile, the semiconductor device according to the embodiments of the present disclosure features good process stability, stable performance, and higher production yield.

The embodiments of the present disclosure further provide a method for manufacturing a semiconductor device. The method for manufacturing a semiconductor device according to the embodiments of the present disclosure is described in detail based on corresponding steps and in combination with corresponding drawings.

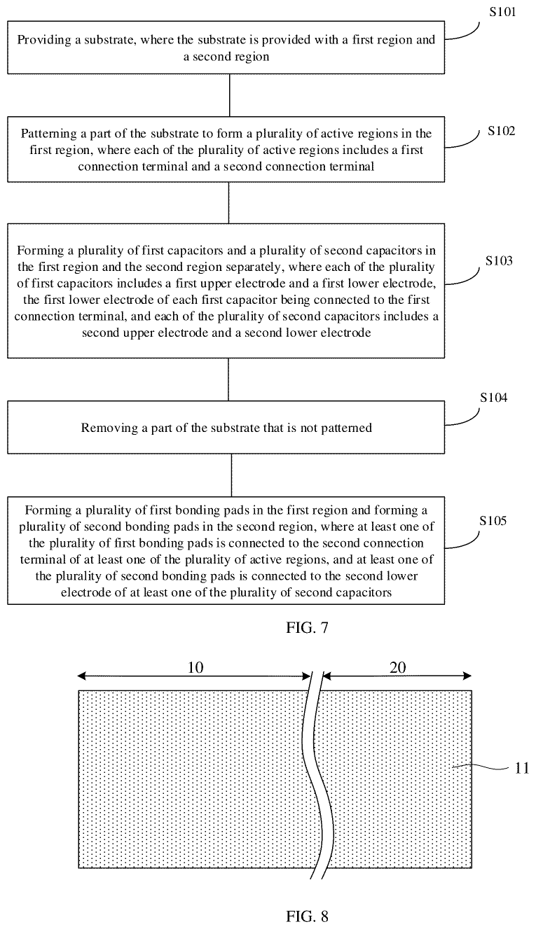

As shown in FIG. 7, FIG. 7 is a schematic flow chart of a method for manufacturing a semiconductor device according to some embodiments of the present disclosure. Specifically, the method includes:
In S101, a substrate is provided, where the substrate is provided with a first region and a second region. Referring to FIG. 8, FIG. 8 is a schematic cross-sectional structural view of a semiconductor device corresponding to step S101. A substrate 11 is provided. The substrate 11 is provided with a first region 10 and a second region 20, and the substrate 11 may be or may include a wafer including silicon, germanium, silicon-germanium, or a group III-V compound such as GaP, GaAs, or GaSb. In some exemplary embodiments, the substrate 11 may be a silicon-on-insulator (SOI) wafer or a germanium-on-insulator (GOI) wafer, and may be doped or undoped. In some exemplary embodiments, the substrate 11 may include both silicon, germanium, silicon-germanium, or a group III-V compound-based crystal such as GaP, GaAs, or GaSb, and a non-semiconductor material. The first region 10 may be a region configured to subsequently form a memory cell, such as a memory cell composed of a transistor and a capacitor. The second region 20 may be a region configured to subsequently form a non-memory cell, such as a non-memory cell including only a capacitor or featuring other functions. The second region 20 may be disposed around the first region 10, or may be disposed on one or more sides of the first region 10.

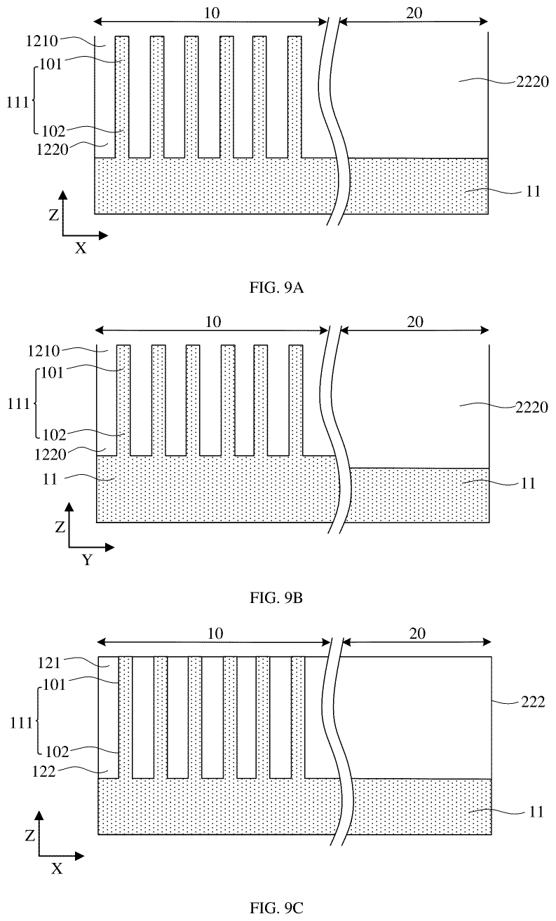

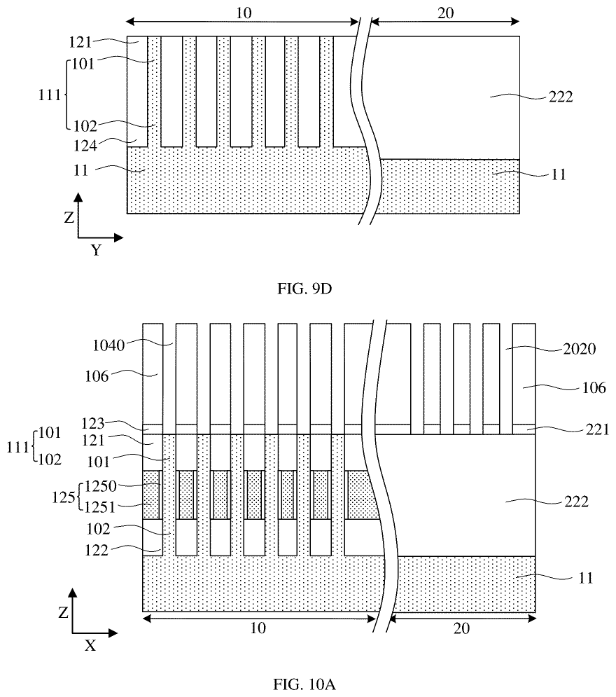

Step S102 is performed to pattern a part of the substrate to form a plurality of active regions in the first region. Each active region includes a first connection terminal and a second connection terminal. Specifically referring to FIGS. 9A to 9D, FIGS. 9A to 9D are schematic cross-sectional structural views of a semiconductor device corresponding to step S102. The first region 10 of the substrate 11 is patterned, and a part of the substrate 11 in the first region 10 is removed, thereby forming the plurality of active regions 111 in the first region 10. Each active region 111 is provided with the first connection terminal 101 and the second connection terminal 102, the active regions 111 extend in the third direction Z, the first connection terminals 101 of the active regions 111 are spaced apart from each other in the first direction X and the second direction Y, and the second connection terminals 102 of the active regions 111 are spaced apart from each other in the first direction X. With continued reference to FIGS. 9A and 9B, when the substrate 11 is patterned to form the active regions 111, first grooves 1210 are formed between the first connection terminals 101 in the first direction X and the second direction Y, and second grooves 1220 are formed between the second connection terminals 102 in the first direction X and the second direction Y. When the substrate 11 in the first region 10 is patterned to form the active regions 111, the substrate 11 in the second region 20 is also patterned, and a third groove 2220 is formed in the substrate 11 in the second region 20.

In some embodiments, in the third direction Z, the depth of the third groove 2220 in the first direction X is less than the depth of the third groove 2220 in the second direction Y.

With continued reference to FIGS. 9C and 9D, after the first grooves 1210, the second grooves 1220, and the third groove 2220 are formed, the first grooves 1210 are filled to form a first insulating dielectric layer 121 for isolating the first connection terminals 101 from each other. The second grooves 1220 are filled to form a first isolation dielectric layer 122 in the first direction X and an isolation dielectric layer 124 in the second direction Y. The first isolation dielectric layer 122 and the isolation dielectric layer 124 may be made of the same or different materials, and the first isolation dielectric layer 122 and the isolation dielectric layer 124 may be formed in the same thin film deposition process or may be formed in different steps, which is not limited in the present disclosure. The third groove 2220 is filled to form a second isolation dielectric layer 222. The first isolation dielectric layer 122, the first insulating dielectric layer 121, the isolation dielectric layer 124, and the second isolation dielectric layer 222 may be formed by using a thin film deposition process. For materials of the film layers, reference may be made to the descriptions in the foregoing embodiments, which will not be repeated here.

The process of patterning the part of the substrate 11 may be achieved by using a combination of processes such as photolithography, etching, and mask deposition.

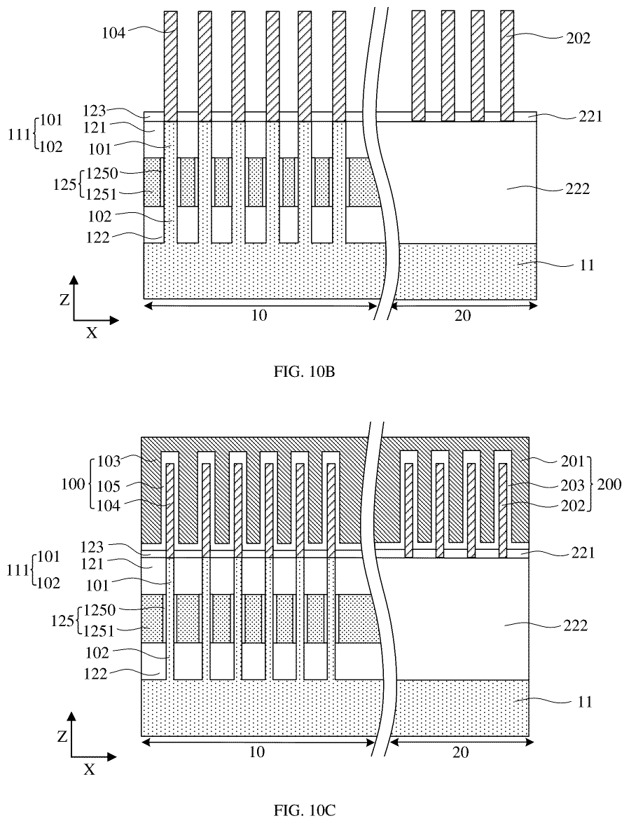

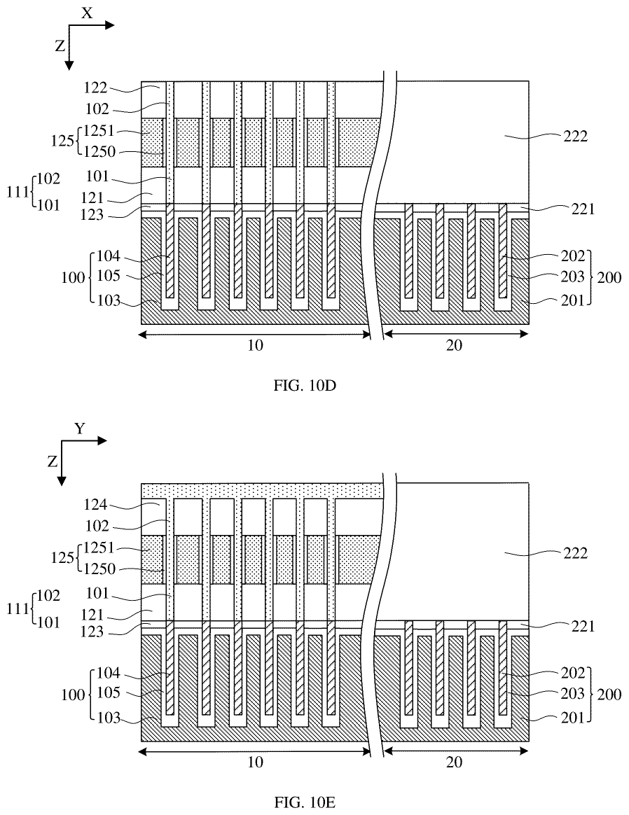

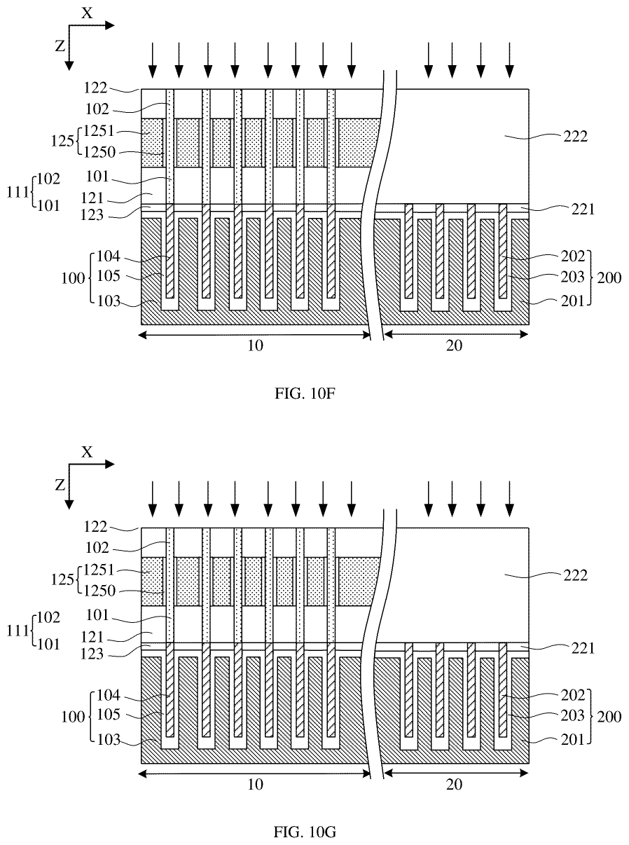

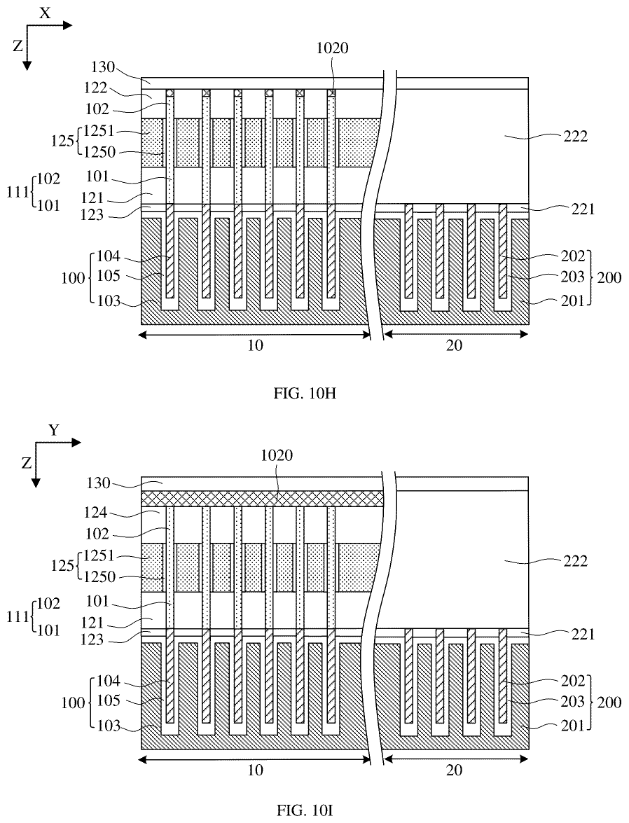

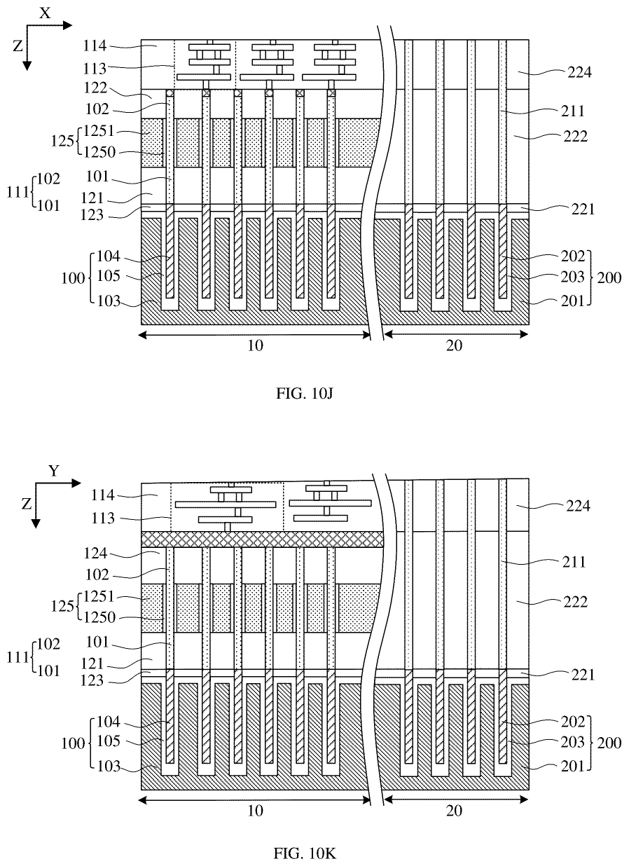

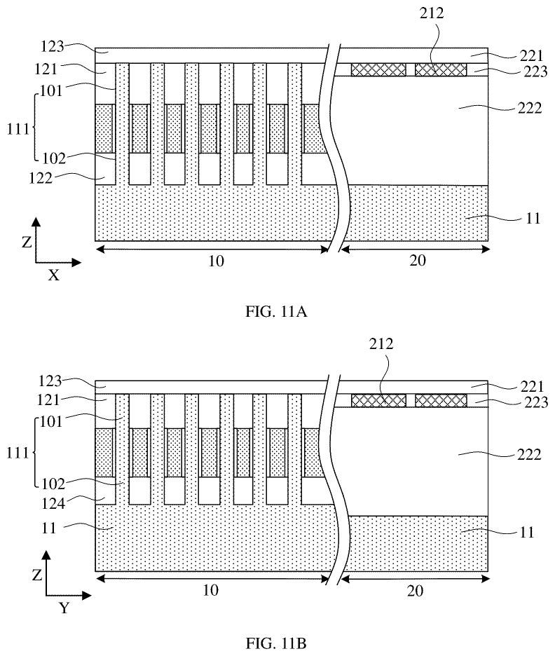

Step S103 is performed to form a plurality of first capacitors and a plurality of second capacitors in the first region and the second region separately. Each first capacitor includes a first upper electrode and a first lower electrode, and the first lower electrode of each first capacitor is connected to the first connection terminal; each second capacitor includes a second upper electrode and a second lower electrode. The process of forming the first capacitors and the second capacitors may refer to FIGS. 10A to 10C. FIGS. 10A to 10C are schematic cross-sectional structural views of a semiconductor device corresponding to step S103. It should be noted that, after the active regions 111 are formed, the method further includes forming gate structures 125 surrounding the active regions 111 between the first connection terminals 101 and the second connection terminals 102 of the active regions 111. The gate structures 125 are connected to each other in the first direction X. In the second direction Y, the gate structures 125 are isolated from each other. The gate structure 125 may be formed before the first insulating dielectric layer 121, the first isolation dielectric layer 122, the isolation dielectric layer 124, and the second isolation dielectric layer 222 are formed, and the specific formation process of the gate structure 125 will not be repeated here.

As shown in FIG. 10A, after the active regions 111 are formed, a first isolation layer 123 is deposited on the surface of the first region 10, and the surface of the first connection terminal 101 of each active region 111 and the surface of the first insulating dielectric layer 121 are both covered by the first isolation layer 123. A second insulating dielectric layer 221 is formed in the second region 20 and covers the surface of the second isolation dielectric layer 222. In some embodiments, the first isolation layer 123 and the second insulating dielectric layer 221 are formed in the same deposition process. After the first isolation layer 123 and the second insulating dielectric layer 221 are formed, a mask layer 106 is deposited in the first region 10 and the second region 20. The mask layer 106 may be of a single-layer structure or a multi-layer composite structure, and the mask layer 106 may be configured to form an intermediate film layer of a pattern, such as a film layer of silicon oxide or silicon nitride and a composite film layer of the two. After the mask layer 106 is formed, a patterning process is performed. First capacitor holes 1040 are formed in the mask layer 106 in the first region 10 and second capacitor holes 2020 are formed in the mask layer 106 in the second region 20 separately by using processes such as photolithography and etching. The first capacitor holes 1040 and the second capacitor holes 2020 are further separately formed in the first isolation layer 123 and the second insulating dielectric layer 221.

With continued reference to FIG. 10B, after the first capacitor holes 1040 and the second capacitor holes 2020 are formed, the first capacitor holes 1040 and the second capacitor holes 2020 are filled with a lower electrode material to form first lower electrodes 104 and second lower electrodes 202, respectively. After the first lower electrodes 104 and the second lower electrodes 202 are formed, the mask layer 106 is removed. The filling of the lower electrode material may be achieved by using a thin film deposition process.

With continued reference to FIG. 10C, after the first lower electrodes 104 and the second lower electrodes 202 are formed, a dielectric layer is deposited on the outer peripheral surfaces of the first lower electrodes 104 and the second lower electrodes 202 to form first dielectric layers 105 and second dielectric layers 203, respectively. After the first dielectric layers 105 and the second dielectric layers 203 are formed, an upper electrode material is deposited on the outer peripheral surfaces of the first dielectric layers 105 and the second dielectric layers 203 to form first upper electrodes 103 and second upper electrodes 201, respectively, thereby forming the first capacitors 100 and the second capacitors 200.

In some embodiments, the first capacitor 100 and the second capacitor 200 are formed simultaneously, and the first capacitor 100 and the second capacitor are formed by using the same process steps.

Step S104 is performed to remove a part of the substrate that is not patterned. With continued reference to FIGS. 10D and 10E, FIGS. 10D and 10E are schematic cross-sectional structural views of a semiconductor device corresponding to step S104. After the first capacitors 100 and the second capacitors 200 are formed, as shown in FIG. 10D, the semiconductor device shown in FIG. 10C is turned over to expose the substrate 11, and then the exposed substrate 11 is removed, so that the second connection terminals 102 connected to each other in the first direction X are in a disconnected state; that is, in the first direction X, the second connection terminals 102 are isolated from each other by the first isolation dielectric layer 122. A part of the substrate on the second connection terminals 102 connected to each other in the second direction Y is still retained, so that the second connection terminals 102 in the second direction Y are still connected to each other, and meanwhile, the substrate 11 in the second region 20 is also removed.

In some embodiments, the part of the substrate that is not patterned is removed by using a thinning process. Specifically, the substrate 11 may be removed by using processes such as chemical mechanical polishing (CMP), wet etching, or dry etching.

After the part of the substrate that is not patterned is removed, the surfaces of the second connection terminals 102, the first isolation dielectric layer 122, and the second isolation dielectric layer 222 are exposed in the first direction X, the surfaces of the second isolation dielectric layer 222 are exposed in the second direction Y, and the connected surface of the second connection terminals 102 are exposed.

With continued reference to FIGS. 10F and 10G, in some embodiments, after the part of the substrate that is not patterned is removed, an ion implantation process is performed on the exposed surface of the second connection terminal 102. FIGS. 10F and 10G are corresponding schematic cross-sectional structural views of the semiconductor device in the first direction X and the second direction Y, respectively, when the ion implantation process is performed. In some embodiments, the ion implantation process may be a source/drain ion implantation (source/drain ion implantation) process. In this process, a dopant (such as arsenic or boron) is introduced into a specific region of each active region 111, such as the first connection terminal 101 and the second connection terminal 102, by means of an ion implantation technology, so as to form an n-type or p-type semiconductor region. These regions will serve as the source and drain of the transistor. In some embodiments, the energy of the ion implantation ranges from 1 Kev to 30 keV, and the ion dose ranges from 1E14 to 1E16.

In some embodiments, with continued reference to FIGS. 10H and 10I, after the part of the substrate that is not patterned is removed, a first sacrificial layer 130 is formed on the exposed surfaces of the second connection terminals 102, the first isolation dielectric layer 122, and the second isolation dielectric layer 222. The first sacrificial layer 130 may be formed by using a thin film deposition process, for example, a CVD process or other processes in which the deposition temperature of a thin film is less than 500° C. The material of the first sacrificial layer 130 may be different from that of the first isolation dielectric layer 122 and the second isolation dielectric layer 222. In some embodiments, the first sacrificial layer 130 may be made of silicon nitride, and the first isolation dielectric layer 122 and the second isolation dielectric layer 222 may be made of silicon oxide. In some embodiments, the first sacrificial layer 130 may also be other materials with higher wavelength absorptance that can offset the phase difference of the reflected light between the interface between the first sacrificial layer 130 and the first isolation dielectric layer 122 and the interface between the first sacrificial layer 130 and the second isolation dielectric layer 222.

In some embodiments, after the first sacrificial layer 130 is formed, a laser annealing process is performed to activate ions implanted into the second connection terminals 102, thereby activating the second connection terminals 102. In some embodiments, the laser annealing process ensures that the H-K material in the first dielectric layer 105 and the second dielectric layer 203 of the first capacitor 100 and the second capacitor 200 is not crystallized while ions are activated, by adopting an ultra-short pulse or other short-wavelength ultra-fast thermal annealing process, including but not limited to a single or a plurality of activated ultra-short pulsed lasers. A laser provides pulsed laser energy density (ED), and a plurality of lasers can adjust the delay time between pulses or lasers to diffuse the heat to an expected depth, so that the amorphous silicon in the channel is completely melted to eliminate voids. For an ultra-short pulsed laser, the energy density ranges from 0.01 to 4 J/cm², the pulse ranges from 10 ns to 1 ms, the delay time may range from 1 ns to 1000 ns, and the available wavelength ranges from 193 nm to 980 nm, such as 532 nm. The crystal used by the laser includes, but is not limited to, an yttrium aluminum garnet (YAG) laser.

In some embodiments, the thickness of the first sacrificial layer 130 may be a quarter of the wavelength of a laser used in the laser annealing process. In some embodiments, the transmittance of the laser into the second connection terminal 102 can be improved by using the first sacrificial layer 130 with a specific thickness. For example, taking the first sacrificial layer 130 being made of silicon nitride (SiN) and the wavelength of the laser being 527 nm as an example, when the first sacrificial layer 130 is not formed on the surface of the second connection terminal 102, the transmittance of the laser into the second connection terminal 102 is 0.63; when the first sacrificial layer 130 is formed on the surface of the second connection terminal 102, the transmittance of the laser into the second connection terminal 102 is greater than or equal to 0.9. Compared with the case without the first sacrificial layer 130, the transmittance is increased by 46%, and the laser absorptance is increased. Meanwhile, in the second region 20, for the second upper electrode 201 of the second region 20, the laser needs to pass through the second isolation dielectric layer 222 and the second insulating dielectric layer 221 to enter the second upper electrode 201. If the first sacrificial layer 130 is not formed, the laser enters the second upper electrode 201 with a transmittance of greater than or equal to 0.8. After the first sacrificial layer 130 is formed, the transmittance of the laser into the second upper electrode 201 is reduced to less than or equal to 0.5. It can be seen that, for each second connection terminal 102 in the first region 10, the laser energy entering the second connection terminal 102 can be increased by adding the first sacrificial layer 30, so that a laser with lower energy can be further adopted, thereby reducing the cost and ensuring the full activation of the second connection terminal 102. For each second upper electrode 201 in the second region 20, the laser energy absorption is reduced, which can reduce damage to the second upper electrode 201 caused by laser energy, thereby effectively preventing defects such as peeling and falling off of the second upper electrode.

In some embodiments, the first sacrificial layer 130 is formed after the ion implantation process.

In some embodiments, after the laser annealing process is performed, the first sacrificial layer 130 is removed, and the first sacrificial layer 130 may be removed by dry etching or wet etching.

With continued reference to FIGS. 10J and 10K, after the first sacrificial layer 130 is removed, a first interconnection structure 113 and a second interconnection structure 211 are formed in the first region 10 and the second region 20, respectively. FIGS. 10J and 10K are corresponding schematic cross-sectional structural views of the semiconductor device in the first direction X and the second direction Y, respectively, when the first interconnection structure 113 and the second interconnection structure 211 are formed.

When the first interconnection structure 113 and the second interconnection structure 211 are formed, an insulating dielectric layer 114 and an insulating dielectric layer 224 are formed simultaneously to isolate the interconnection structures from each other. In some embodiments, the first interconnection structure 113 may be a plurality of layers of metal interconnects formed in the insulating dielectric layer 114 and connected to at least the second connection terminals 102. The second interconnection structure 211 may be a single-layer metal interconnect formed in the insulating dielectric layer 224 and the second isolation dielectric layer 222 and connected to at least the second lower electrodes 202.

Step S105 is performed to form a plurality of first bonding pads and second bonding pads in the first region and the second region, where at least one first bonding pad is connected to the second connection terminal of at least one active region, and at least one second bonding pad is connected to the second lower electrode of at least one second capacitor. In some embodiments, the first bonding pads and the second bonding pads are formed after the first interconnection structure and the second interconnection structure are formed. In some embodiments, the first bonding pads 112 and the second bonding pads 210 are both metal pads for direct bonding, and the process of forming the first bonding pads 112 and the second bonding pads 210 adopts the process of forming directly bonded metal pads, which will not be repeated here. For the finally formed structures, reference is made to FIGS. 2, 3, 5, and 6.

In some embodiments, a common connection terminal is formed in the second insulating dielectric layer before the first capacitors and the second capacitors are formed. As shown in FIGS. 11A and 11B, FIGS. 11A and 11B are corresponding schematic cross-sectional structural views of the semiconductor device in the first direction X and the second direction Y, respectively, when the common connection terminal is formed. Before the first isolation layer 123 and the second insulating dielectric layer 221 are formed, a second isolation layer 223 is formed on the surface of the second isolation dielectric layer 222 in the second region 20. Next, the pattern of the common connection terminal 212 is formed in the second isolation layer 223 by a patterning process. Then, the pattern of the common connection terminal 212 is filled to form the common connection terminal 212. After the common connection terminal 212 is formed, the foregoing process of forming the first capacitors and the second capacitors and subsequent steps are performed. For details, reference can be made to the foregoing descriptions. The finally formed structures are as shown in FIGS. 3 and 6.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

What is claimed is:

1. A semiconductor device, comprising:
a first region and a second region;
a plurality of active regions, wherein the plurality of active regions are disposed in the first region, and each of the plurality of active regions comprises a first connection terminal and a second connection terminal;
a plurality of first capacitors, wherein the plurality of first capacitors are disposed in the first region, each of the plurality of first capacitors comprises a first upper electrode and a first lower electrode, and the first lower electrode of each first capacitor is connected to the first connection terminal;
a plurality of second capacitors, wherein the plurality of second capacitors are disposed in the second region, and each of the plurality of second capacitors comprises a second upper electrode and a second lower electrode;
a plurality of first bonding pads, wherein the plurality of first bonding pads are disposed in the first region, and at least one of the plurality of first bonding pads is connected to the second connection terminal of at least one of the plurality of active regions; and
a plurality of second bonding pads, wherein the plurality of second bonding pads are disposed in the second region, and at least one of the plurality of second bonding pads is connected to the second lower electrode of at least one of the plurality of second capacitors.

2. The semiconductor device according to claim 1, wherein the first connection terminals of the plurality of active regions are spaced apart from each other in a first direction and a second direction, the second connection terminals of the plurality of active regions are isolated from each other in the first direction, and the second connection terminals of the plurality of active regions are connected to each other in the second direction.

3. The semiconductor device according to claim 2, further comprising a first interconnection structure located in the first region and a second interconnection structure located in the second region, wherein the first interconnection structure is disposed between the second connection terminals of the plurality of active regions and the plurality of first bonding pads, and connects the second connection terminals and the plurality of first bonding pads; the second interconnection structure is disposed between the second lower electrodes of the plurality of second capacitors and the plurality of second bonding pads, and connects the second lower electrodes and the plurality of second bonding pads.

4. The semiconductor device according to claim 3, further comprising a first dielectric layer combination located in the first region and a second dielectric layer combination located in the second region, wherein the first dielectric layer combination comprises a first isolation dielectric layer, and the second dielectric layer combination comprises a second isolation dielectric layer, the first isolation dielectric layer being disposed between the second connection terminals arranged in the first direction, and the second isolation dielectric layer being disposed between second interconnection structures.

5. The semiconductor device according to claim 4, wherein the first dielectric layer combination further comprises a first insulating dielectric layer, and the second dielectric layer combination further comprises a second insulating dielectric layer, the first insulating dielectric layer being disposed between the first connection terminals, and the second insulating dielectric layer being disposed between the second lower electrodes of the plurality of second capacitors.

6. The semiconductor device according to claim 1, wherein the second region further comprises a common connection terminal, the second lower electrodes of the plurality of second capacitors are connected to the common connection terminal, and the common connection terminal is connected to at least one of the plurality of second bonding pads.

7. The semiconductor device according to claim 6, further comprising a second interconnection structure located in the second region, wherein the second interconnection structure is disposed between the common connection terminal and one of the plurality of second bonding pads, and connects the common connection terminal and the second bonding pad.

8. A method for manufacturing a semiconductor device, comprising:
providing a substrate, wherein the substrate is provided with a first region and a second region;
patterning a part of the substrate to form a plurality of active regions in the first region, wherein each of the plurality of active regions comprises a first connection terminal and a second connection terminal;
forming a plurality of first capacitors and a plurality of second capacitors in the first region and the second region separately, wherein each of the plurality of first capacitors comprises a first upper electrode and a first lower electrode, the first lower electrode of each first capacitor being connected to the first connection terminal, and each of the plurality of second capacitors comprises a second upper electrode and a second lower electrode;
removing a part of the substrate that is not patterned; and
forming a plurality of first bonding pads in the first region and forming a plurality of second bonding pads in the second region, wherein at least one of the plurality of first bonding pads is connected to the second connection terminal of at least one of the plurality of active regions, and at least one of the plurality of second bonding pads is connected to the second lower electrode of at least one of the plurality of second capacitors.

9. The method for manufacturing a semiconductor device according to claim 8, wherein forming the plurality of active regions in the first region comprises:
patterning the substrate to form a plurality of active regions extending in a third direction in the first region, each of the plurality of active regions comprising the first connection terminal and the second connection terminal disposed in the third direction, wherein the first connection terminals of the plurality of active regions are spaced apart from each other in a first direction and a second direction, and the second connection terminals of the plurality of active regions are connected to each other in the first direction and the second direction.

10. The method for manufacturing a semiconductor device according to claim 9, wherein when the substrate is patterned to form the plurality of active regions, first grooves are formed between the first connection terminals, and second grooves are formed between the second connection terminals in the second direction;
when a part of the substrate in the first region is patterned to form the plurality of active regions, a part of the substrate in the second region is also patterned to form a third groove in the substrate in the second region;
a first insulating dielectric layer and a first isolation dielectric layer are formed in the first grooves and the second grooves separately, and a second isolation dielectric layer is formed in the third groove.

11. The method for manufacturing a semiconductor device according to claim 10, wherein after the first insulating dielectric layer, the first isolation dielectric layer, and the second isolation dielectric layer are formed by filling, a second insulating dielectric layer is formed on the second isolation dielectric layer; after the first insulating dielectric layer and the second insulating dielectric layer are formed, the plurality of first capacitors and the plurality of second capacitors are formed.

12. The method for manufacturing a semiconductor device according to claim 11, wherein before the plurality of first capacitors and the plurality of second capacitors are formed, the method further comprises forming a common connection terminal in the second insulating dielectric layer, the common connection terminal being connected to the second lower electrode of at least one of the plurality of second capacitors.

13. The method for manufacturing a semiconductor device according to claim 10, wherein removing the part of the substrate that is not patterned comprises: thinning the part of the substrate that is not patterned, so that the second connection terminals of the plurality of active regions are isolated from each other in the first direction, the second connection terminals of the plurality of active regions remain connected to each other in the second direction, and meanwhile, the second connection terminals, a surface of the first isolation dielectric layer, and a surface of the second isolation dielectric layer are exposed;
after the part of the substrate that is not patterned is removed, a first sacrificial layer is formed on the second connection terminals, the surface of the first isolation dielectric layer, and the surface of the second isolation dielectric layer that are exposed;
after the first sacrificial layer is formed, a laser annealing process is performed to activate the second connection terminals;
after the second connection terminals are activated, the first sacrificial layer is removed to form the plurality of first bonding pads and the plurality of second bonding pads in the first region and the second region separately.

14. The method for manufacturing a semiconductor device according to claim 13, wherein before the plurality of first bonding pads and the plurality of second bonding pads are formed, a first interconnection structure connected to the second connection terminals is formed, and a second interconnection structure connected to the second lower electrodes is formed.

15. The method for manufacturing a semiconductor device according to claim 13, wherein a thickness of the first sacrificial layer is a quarter of a wavelength of a laser used in the laser annealing process.

16. The method for manufacturing a semiconductor device according to claim 13, wherein before the first sacrificial layer is formed, an ion implantation process is performed on the second connection terminals that are exposed.

17. The method for manufacturing a semiconductor device according to claim 8, wherein the plurality of second capacitors are formed in the second region while the plurality of first capacitors are formed in the first region.
